(19) United States
(12) Patent Application Publication
(10) Pub. No.: US 2017/0076800 A1
(43) Pub. Date: Mar. 16, 2017

(54) VOLTAGE GENERATING CIRCUIT AND SEMICONDUCTOR MEMORY DEVICE

(71) Applicant: KABUSHIKI KAISHA TOSHIBA, Tokyo (JP)

(72) Inventor: Junji MUSHA, Yokohama Kanagawa (JP)

(21) Appl. No.: 15/207,216

(22) Filed: Jul. 11, 2016

(30) Foreign Application Priority Data
Sep. 11, 2015 (JP) 2015-180095

(51) Int. Cl. G11C 16/08; G05F 3/02; G11C 16/30

(52) U.S. Cl. CPC G11C 16/08; G11C 16/30; G05F 3/02

(57) ABSTRACT

A voltage generating circuit includes a first booster circuit that generates a first boosted voltage from a voltage supplied to an input thereof, a first transistor having a first terminal electrically connected to the input of the first booster circuit, a second booster circuit that generates a second boosted voltage from a voltage supplied to an input thereof, a second transistor having a first terminal electrically connected to the input of the second booster circuit and a second terminal electrically connected to a voltage source, and a control circuit electrically connected between the voltage source and a second terminal of the first transistor, the control circuit configured to cut off the voltage source from the second terminal of the first transistor in accordance with a voltage level of the voltage source.

### CROSS-REFERENCE TO RELATED APPLICATION

This application is based upon and claims the benefit of priority from Japanese Patent Application No. 2015-180095, filed Sep. 11, 2015, the entire contents of which are incorporated herein by reference.

### FIELD

Embodiments described herein relate generally to a semiconductor memory device including a voltage generating circuit which includes a booster circuit.

### BACKGROUND

Generally, a semiconductor memory device, such as a NAND type flash memory requires a voltage higher than a power supply voltage supplied from an external power supply, in order to perform a data write operation, a data erasing operation, and a data read operation. Thus, the semiconductor memory device includes a voltage generating circuit that boosts the power supply voltage.

### DESCRIPTION OF THE DRAWINGS

FIG. 1 is a diagram illustrating an overall configuration of a semiconductor memory device according to a first embodiment.

FIG. 2 is a diagram illustrating a configuration of a voltage generating circuit according to the first embodiment.

FIG. 3 is a diagram illustrating a configuration of a booster circuit according to the first embodiment.

FIGS. 4A and 4B are diagrams illustrating an operation of the voltage generating circuit according to the first embodiment.

FIGS. 5A and 5B are diagrams illustrating an operation of the voltage generating circuit according to the first embodiment.

FIG. 6 is a diagram illustrating operational modes of the voltage generating circuit according to the first embodiment.

FIG. 7 is a diagram illustrating a configuration of a voltage generating circuit in a modification example of the first embodiment.

FIG. 8 is a diagram illustrating a peak current reduction effect of the voltage generating circuit according to the first embodiment.

FIG. 9 is a diagram illustrating timings of peak currents, at which the peak current reduction effect shown in FIG. 8 would be observed.

FIG. 10 is a diagram illustrating a configuration of a voltage generating circuit according to a second embodiment.

FIG. 11 is a diagram illustrating an operation of the voltage generating circuit according to the second embodiment.

### DETAILED DESCRIPTION

Embodiments provide a voltage generating circuit and a semiconductor memory device that enable reduction of a peak current and consumed power.

In general, according to embodiments, a voltage generating circuit includes a first booster circuit that generates a first boosted voltage from a voltage supplied to an input thereof, a first transistor having a first terminal electrically connected to the input of the first booster circuit, a second booster circuit that generates a second boosted voltage from a voltage supplied to an input thereof, a second transistor having a first terminal electrically connected to the input of the second booster circuit and a second terminal electrically connected to a voltage source, and a control circuit electrically connected between the voltage source and a second terminal of the first transistor, the control circuit configured to cut off the voltage source from the second terminal of the first transistor in accordance with a voltage level of the voltage source.

Hereinafter, embodiments will be described with reference to the accompanying drawings. In the following descriptions, components which have the same function and the same configuration are denoted by the same reference numbers. Here, descriptions will be made using a planar NAND type flash memory as an example of a semiconductor memory device including a voltage generating circuit. In the planar NAND type flash memory, memory cell transistors are two-dimensionally arranged on a semiconductor substrate.

### 1. First Embodiment

A semiconductor memory device including a voltage generating circuit according to a first embodiment will be described.

1-1. Overall Configuration of Semiconductor Memory Device

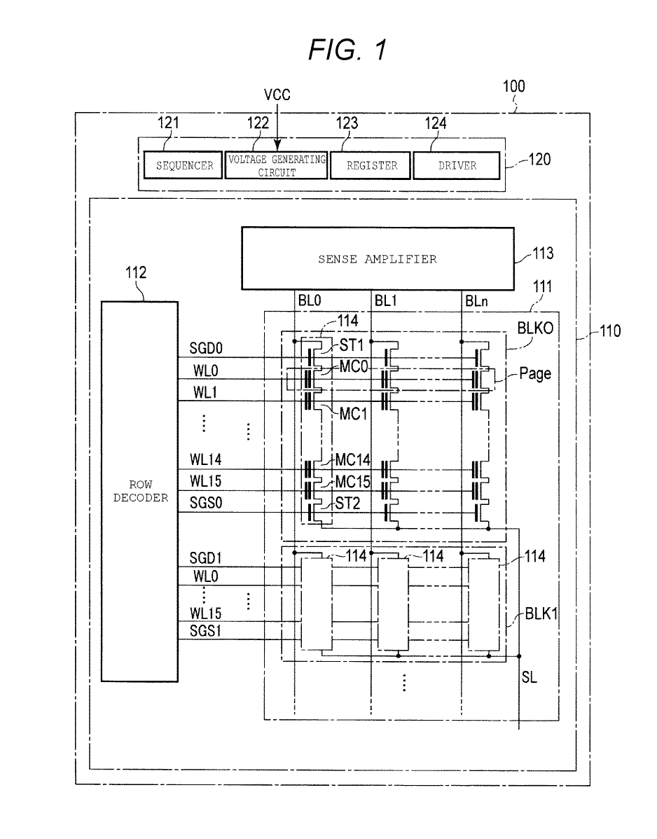

The overall configuration of the semiconductor memory device according to the first embodiment will be described with reference to FIG. 1.

As illustrated in FIG. 1, a NAND type flash memory 100 includes a core section 110 and a peripheral circuit 120.

The core section 110 includes a memory cell array 111, a row decoder 112, and a sense amplifier 113.

The memory cell array 111 includes a plurality of blocks BLK0, BLK1, . . . . Each of the blocks includes a plurality of nonvolatile memory cell transistors. Hereinafter, a block BLK refers to each of the blocks BLK0, BLK1, . . . . Pieces of data in one block BLK are collectively erased, for example. A range in which data is erased is not limited to one block BLK, however. A plurality of blocks may be collectively erased or some regions in one block BLK may be collectively erased.

Erasing of data is disclosed in, for example, “Nonvolatile Semiconductor Memory Device,” U.S. patent application Ser. No. 12/694,690, filed Jan. 27, 2010, and “Nonvolatile Semiconductor Memory Device,” U.S. patent application Ser. No. 13/235,389, filed Sep. 18, 2011. The entire contents of these patent applications are incorporated by reference into this specification.

The block BLK includes a plurality of NAND strings 114 in each of which memory cell transistors are connected to each other in series. The memory cell transistors are two-dimensionally arranged on a semiconductor substrate. The number of NAND strings 114 included in one block may be arbitrary.

Each of the NAND strings 114 includes 16 pieces of memory cell transistors MC0, MC1, . . . , and MC15, and selection transistors ST1 and ST2, for example. Hereinafter, a memory cell transistor MC refers to each of the memory cell transistors MC0 to MC15.

The memory cell transistor MC includes a layered gate which includes a control gate and a charge storage layer. The memory cell transistor MC stores data in a nonvolatile manner. The memory cell transistor MC may be a metal-oxide-nitride-oxide-silicon (MONOS) type which uses an insulating film for the charge storage layer or may be a floating gate (FG) type which uses a conductive film for the charge storage layer. The number of memory cell transistors MC is not limited to 16, and may be 8, 32, 64, 128, or the like. The number of memory cell transistors MC is not limited to a specific value.

Regarding the memory cell transistors MC0 to MC15, a source of one memory cell transistor is connected to a drain of another memory cell transistor in series. The drain of the memory cell transistor MTO on one end side of this series connection is connected to a source of the selection transistor ST1. The source of the memory cell transistor MT15 on another end side thereof is connected to a drain of the selection transistor ST2.

Gates of selection transistors ST1 in the block BLK are commonly connected to the same selection gate line. In the example of FIG. 1, the gates of the selection transistors ST1 in the block BLK0 are commonly connected to a selection gate line SGD0. Gates of selection transistors ST1 (not illustrated) in the block BLK1 are commonly connected to a selection gate line SGD1. Similarly, gates of the selection transistors ST2 in the block BLK0 are commonly connected to a selection gate line SGS0. Gates of selection transistors ST2 (not illustrated) in the block BLK1 are commonly connected to a selection gate line SGS1. Hereinafter, the described selection gate line SGD refers to each of selection gate lines SGD0, SGD1, . . . , and the described selection gate line SGS refers to each of selection gate lines SGS0, SGS1, . . . .

Control gates of the memory cell transistors MC in NAND strings 114 in the block BLK are respectively and commonly connected to word lines WL0 to WL15. That is, the control gates of the memory cell transistors MC0 in the NAND strings 114 are commonly connected to the word line WL0. Similarly, control gates of the memory cell transistors MC1 to MC15 are commonly and respectively connected to the word lines WL1 to WL15.

Drains of selection transistors ST1 in NAND strings 114 in the same line among NAND strings 114 which are arranged in matrix configuration in the memory cell array 111 are respectively and commonly connected to bit lines BL0, BL1, . . . , BLn (n is a natural number of 0 or more). That is, each of the bit lines BL0 to BLn is commonly connected to NAND strings 114 in the plurality of blocks BLK. Hereinafter, the described bit line BL refers to each of the bit lines BL0, BL1, . . . , BLn.

Sources of the selection transistors ST2 in the block BLK are commonly connected to a source line SL. That is, for example, the NAND strings 114 in the plurality of blocks BLK are commonly connected to the source line SL.

The row decoder 112 decodes an address of a block BLK or an address of a page, for example, when data is written or read, and selects a word line corresponding to a page to be written or read. The row decoder 112 respectively applies appropriate voltages to the selected word line WL, the non-selected word line WL, and the selection gate lines SGD and SGS.

When data is read, the sense amplifier 113 senses and amplifies data read from the memory cell transistor MC to the bit line BL. When data is written, the sense amplifier 113 transfers write data to the memory cell transistor MC.

The peripheral circuit 120 includes a sequencer 121, a voltage generating circuit 122, a register 123, and a driver 124.

The sequencer 121 controls the entire operation of the NAND type flash memory 100.

The voltage generating circuit 122 generates voltages required for write, read, and erasing of data, and supplies the generated voltages to the driver 124. The voltage generating circuit 122 includes a plurality of booster circuits. The voltage generating circuit 122 will be described later in detail.

The driver 124 respectively supplies the voltages required for write, read, and erasing of data to the row decoder 112, the sense amplifier 113, and the source line SL. The row decoder 112 and the sense amplifier 113 transfer the voltage supplied from the driver 124, to the memory cell transistor MC.

The register 123 stores various signals. For example, a status of a write operation or an erasing operation of data is stored. An external controller is notified of whether or not the operation is normally completed, based on the status, for example. The register 123 may also store various tables.

The above descriptions are made by using a planar NAND type flash memory in which memory cell transistors are two-dimensionally arranged on a semiconductor substrate, as an example. However, this embodiment may be applied to a three-dimensional multilayer nonvolatile semiconductor memory in which memory cell transistors are three-dimensionally arranged on a semiconductor substrate.

A configuration of a memory cell array in the three-dimensional multilayer nonvolatile semiconductor memory is disclosed in, for example, “Three-dimensional Multilayer Nonvolatile Semiconductor Memory,” U.S. patent application Ser. No. 12/407,403, filed Mar. 19, 2009, “Three-dimensional Multilayer Nonvolatile Semiconductor Memory,” U.S. patent application Ser. No. 12/406,524, filed Mar. 18, 2009, “Nonvolatile Semiconductor Memory Device,” U.S. patent application Ser. No. 13/816,799, filed Sep. 22, 2011, and “Semiconductor Memory and Method for Manufacturing Same,” U.S. patent application Ser. No. 12/532,030, filed Mar. 23, 2009. The entire contents of these patent applications are incorporated by reference into this specification.

1-2. Voltage Generating Circuit

Next, a configuration of the voltage generating circuit 122 included in the NAND type flash memory 100 will be described.

### 1-2-1. Circuit Configuration

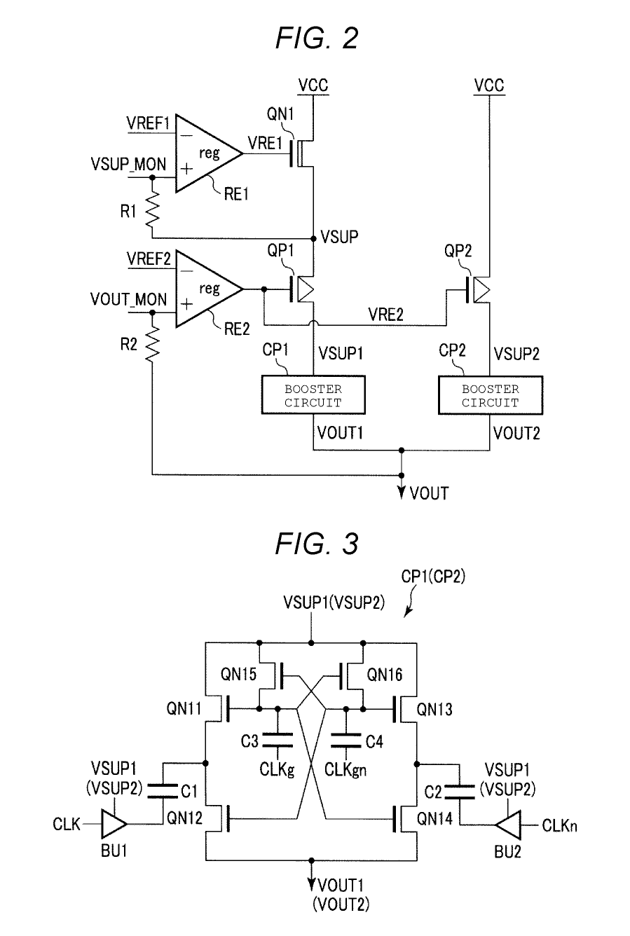

A circuit configuration of the voltage generating circuit 122 will be described with reference to FIG. 2.

The voltage generating circuit 122 includes voltage regulators (or error amplifiers) RE1 and RE2, booster circuits CP1 and CP2, an n-channel MOS field effect transistor (nMOS transistor) QN1, p-channel MOS field effect transistors (pMOS transistors) QP1 and QP2, and resistors R1 and R2. The nMOS transistor QN1 is a depletion type transistor.

Connections between the circuit elements included in the voltage generating circuit 122 are as follows.

An external power supply VCC is supplied to a drain of the nMOS transistor QN1. A source of the nMOS transistor QN1 is connected to a source of the pMOS transistor QP1. The source of the nMOS transistor QN1 is also connected to a non-inverting input terminal (+) of the regulator RE1 through the resistor R1. A reference voltage VREF1 is supplied to an inverting input terminal (−) of the regulator RE1. An output terminal of the regulator RE1 is connected to a gate of the nMOS transistor QN1. A drain of the pMOS transistor QP1 is connected to the booster circuit CP1.

The external power supply VCC is supplied to a source of the pMOS transistor QP2. A drain of the pMOS transistor QP2 is connected to the booster circuit CP2.

Output sections of the booster circuits CP1 and CP2 are connected to a non-inverting input terminal (+) of the regulator RE2 through the resistor R2. A reference voltage VREF2 is supplied to an inverting input terminal (−) of the regulator RE2. An output terminal of the regulator RE2 is connected to a gate of the pMOS transistor QP1 and a gate of the pMOS transistor QP2.

Next, a circuit configuration of the booster circuits CP1 and CP2 will be described with reference to FIG. 3.

The booster circuit CP1 (or CP2) includes nMOS transistors QN11, QN12, QN13, QN14, QN15, and QN16, capacitors C1, C2, C3, and C4, and buffers BU1 and BU2. A voltage VSUP1 (or VSUP2) is supplied to power-supply terminals of the buffers BU1 and BU2. A clock signal CLK is supplied to an input terminal of the buffer BU1, and a clock signal CLKn is supplied to an input terminal of the buffer BU2. A clock signal CLKg is supplied to an end of the capacitor C3, and a clock signal CLKgn is supplied to an end of the capacitor C4.

If the voltage VSUP1 is supplied to an input section of the booster circuit CP1, the booster circuit CP1 boosts the voltage VSUP1 so as to be doubled, and outputs the boosted voltage as a voltage VOUT1 (=VSUP1×2). If a voltage VSUP2 is supplied to an input section of the booster circuit CP2, the booster circuit CP2 boosts the voltage VSUP2 so as to be doubled, and outputs the boosted voltage as a voltage VOUT2 (=VSUP2×2).

1-2-2. Operation

An operation of the voltage generating circuit 122 will be described with reference to FIG. 2 and FIGS. 4A to 6.

As an operation example, a first case where the external power supply VCC is 2.5 V, and a second case where the external power supply VCC is 3.7 V will be described below. Here, it is assumed that threshold voltages of the pMOS transistors QP1 and QP2 are 0.7 V.

(1) Case where External Power Supply VCC is 2.5 V

The external power supply VCC (2.5 V) is input to the source of the pMOS transistor QP2. The pMOS transistor QP2 transitions between an OFF state and an ON state, in accordance with a control voltage VRE2 supplied to the gate thereof. The pMOS transistor QP2 supplies the external power supply VCC to the booster circuit CP2 from the drain thereof in accordance with the transitioned state. The pMOS transistor QP2 is in the ON state when the control voltage VRE2 is equal to or less than “VCC−Vth” (1.8V), and is in the OFF state when the control voltage VRE2 is greater than 1.8 V. An operation of outputting the control voltage VRE2 will be described below.

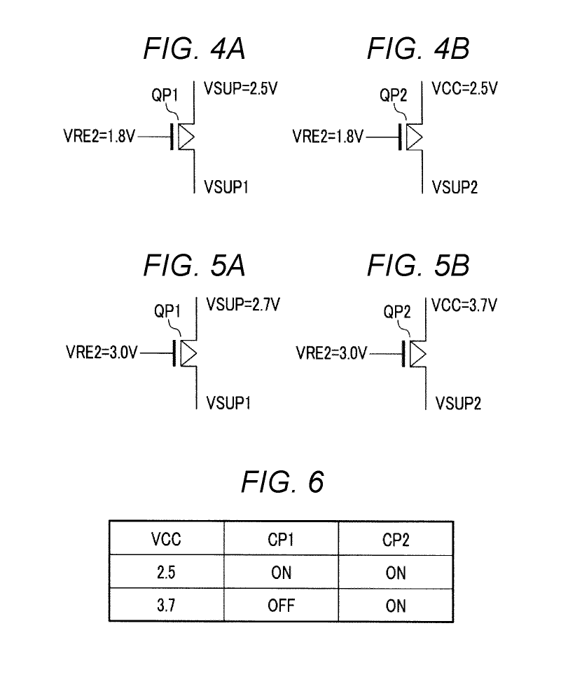

As illustrated in FIG. 4B, if, for example, the control voltage VRE2 is 1.8 V, the pMOS transistor QP2 is in the ON state. Thus, the pMOS transistor QP2 supplies the external power supply VCC, which is input to the source of the pMOS transistor QP2, to the booster circuit CP2. The voltage supplied to the booster circuit CP2 is referred to as the voltage VSUP2. The booster circuit CP2 boosts the voltage VSUP2 and outputs the boosted voltage VSUP2 as the voltage VOUT2.

The external power supply VCC (2.5 V) is input to the drain of the depletion type nMOS transistor QN1. If the external power supply VCC (2.5V) is input, the nMOS transistor QN1 is in the ON state. Thus, the voltage of 2.5 V is transferred to the source of the nMOS transistor QN1. The voltage at the source thereof is referred to as the voltage VSUP.

The voltage VSUP (2.5 V) is input to the non-inverting input terminal (+) of the regulator RE1 through the resistor R1. The voltage input to the non-inverting input terminal (+) is described as a monitored voltage VSUP_MON. The reference voltage VREF1 is input to the inverting input terminal (−) of the regulator RE1.

The regulator RE1 compares the monitored voltage VSUP_MON and the reference voltage VREF1 to each other, and outputs the control voltage VRE1 in accordance with a result of the comparison. That is, the regulator RE1 receives a difference between the monitored voltage VSUP_MON and the reference voltage VREF1, and adjusts the control voltage VRE1 in accordance with the received difference, so as to keep the voltage VSUP to be a constant voltage (here, for example, 2.7 V). However, when the external power supply VCC is smaller than 2.7 V, the voltage VSUP becomes the same voltage as the external voltage VCC. Here, since the external power supply VCC is 2.5 V, the voltage VSUP is 2.5 V which is the same as the external voltage VCC. “VSUP>VCCmin” is established between a lower limit voltage VCCmin of an allowable voltage range of the external power supply VCC, and the voltage VSUP.

The voltage VSUP (2.5 V) is input to the source of the pMOS transistor QP1. The pMOS transistor QP1 performs transition between the OFF state and the ON state, in accordance with a control voltage VRE2 supplied to the gate thereof. The pMOS transistor QP1 supplies the voltage VSUP to the booster circuit CP1 from the drain thereof in accordance with the transitioned state. The pMOS transistor QP1 is in the ON state when the control voltage VRE2 is equal to or less than “VSUP−Vth” (1.8 V), and is in the OFF state when the control voltage VRE2 is greater than 1.8 V.

As illustrated in FIG. 4A, if, for example, the control voltage VRE2 is 1.8 V, the pMOS transistor QP1 is in the ON state. Thus, the pMOS transistor QP1 supplies the voltage VSUP which is input to the source of the pMOS transistor QP1, to the booster circuit CP1. The voltage supplied to the booster circuit CP1 is referred to as the voltage VSUP1. The booster circuit CP1 boosts the voltage VSUP1 and outputs the boosted voltage VSUP1 as the voltage VOUT1.

The two voltages VOUT1 and VOUT2 are added, and whereby the output voltage VOUT is obtained. The output voltage VOUT is input to the non-inverting input terminal (+) of the regulator RE2 through the resistor R2. The voltage input to the non-inverting input terminal (+) is referred to as a monitored voltage VOUT_MON. The reference voltage VREF2 is input to the inverting input terminal (−) of the regulator RE2. The regulator RE2 receives a difference between the monitored voltage VOUT_MON and the reference voltage VREF2, and adjusts the control voltage VRE2 in accordance with the obtained difference, so as to keep the output voltage VOUT to be constant. Thus, the output voltage VOUT is controlled so as to be a desired constant voltage.

In this manner, when the external power supply VCC is 2.5 V, both of the pMOS transistors QP1 and QP2 are in the ON state, and 2.5 V is supplied to the booster circuits CP1 and CP2 together. Thus, as illustrated in FIG. 6, both booster circuits CP1 and CP2 are operated and each of the voltages VSUP1 and VSUP2 is boosted. Accordingly, the output voltage VOUT is boosted up to the desired constant voltage.

The boosted output voltage is supplied to a word line WL connected to a memory cell MC, for example, when any of a data write operation, a data erasing operation, and a data read operation is performed.

(2) Case where External Power Supply VCC is 3.7 V

The external power supply VCC (3.7 V) is input to the source of the pMOS transistor QP2. As illustrated in FIG. 5B, for example, the pMOS transistor QP2 is in the ON state because the control voltage VRE2 supplied to the gate of the pMOS transistor QP2 is 3.0V. Thus, the pMOS transistor QP2 supplies the external power supply VCC which is input to the source thereof as the voltage VSUP2, to the booster circuit CP2. The booster circuit CP2 boosts the voltage VSUP2 and outputs the boosted voltage VSUP2 as the voltage VOUT2.

The external power supply VCC (3.7 V) is input to the drain of the depletion type nMOS transistor QN1. If the external power supply VCC (3.7V) is input, the nMOS transistor QN1 steps down the external power supply VCC under the control of the regulator RE1. As illustrated in FIG. 5A, the voltage at the source of the nMOS transistor QN1 is the voltage VSUP (2.7 V).

The voltage VSUP (2.7 V) is input to the non-inverting input terminal of the regulator RE1 through the resistor R1, as the monitored voltage VSUP_MON. The regulator RE1 obtains a difference between the monitored voltage VSUP_MON and the reference voltage VREF1, and adjusts the control voltage VRE1 in accordance with the obtained difference, so as to keep the voltage VSUP to be constant. Thus, the voltage VSUP is controlled to be a constant voltage of 2.7 V.

The voltage VSUP (2.7 V) is input to the source of the pMOS transistor QP1. At this time, as illustrated in FIG. 5A, since the control voltage VRE2 output from the regulator RE2 is 3.0 V, the pMOS transistor QP1 is in the OFF state. Thus, the pMOS transistor QP1 does not supply the voltage VSUP input to the source thereof, to the booster circuit CP1.

The voltage VOUT1 is not output from the booster circuit CP1 and the voltage VOUT2 output from the booster circuit CP2 is used as the output voltage VOUT. The output voltage VOUT is input to the non-inverting input terminal (+) of the regulator RE2 through the resistor R2, as the monitored voltage VOUT_MON. The regulator RE2 obtains a difference between the monitored voltage VOUT_MON and the reference voltage VREF2, and adjusts the control voltage VRE2 in accordance with the obtained difference, so as to keep the output voltage VOUT to be constant. Thus, the voltage VOUT is controlled so as to be a desired constant voltage.

In this manner, when the external power supply VCC is 3.7 V, the pMOS transistor QP1 is in the OFF state, and the pMOS transistor QP2 is in the ON state. The external power supply VCC (3.7 V) is supplied only to the booster circuit CP2. Thus, as illustrated in FIG. 6, only the booster circuit CP2 is operated so as to boost the voltage VSUP2. Accordingly, the output voltage VOUT is boosted up to the desired constant voltage.

The boosted output voltage is supplied to a word line WL connected to a memory cell MC, for example, when any of a data write operation, a data erasing operation, and a data read operation is performed. In addition, the output voltage may be used to generate a voltage supplied to the word line WL.

### 1-3. Modification Example

For the booster circuits CP1 and CP2 in the first embodiment, booster circuits may include the circuit illustrated in FIG. 3 connected in a plurality of stages. In the booster circuits CP1 and CP2, the number of the stages may be different from each other. Here, a modification example in which a booster circuit which includes the circuit illustrated in FIG. 3 connected in two stages is used as the booster circuit CP1 will be described. A difference from the first embodiment will be described below.

1-3-1. Voltage Generating Circuit

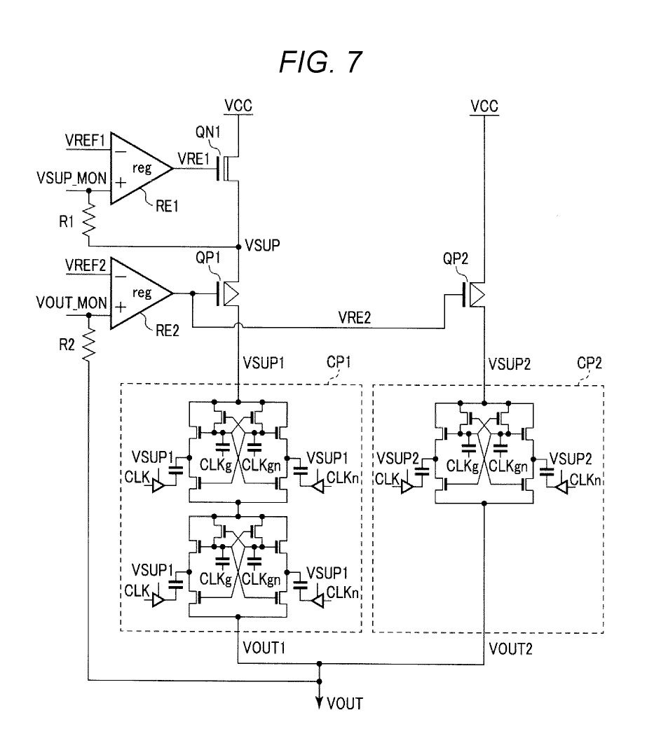

A configuration of a voltage generating circuit in the modification example will be described with reference to FIG. 7. The voltage generating circuit in the modification example includes a booster circuit CP1a. In the booster circuit CP1a, the circuit illustrated in FIG. 3 is implemented in two stages. The booster circuit CP1a boosts the input voltage VSUP1 so as to be tripled and outputs the boosted voltage VSUP1 as the voltage VOUT1 (=VSUP1×3). The booster circuit CP2 boosts the input voltage VSUP2 so as to be doubled and outputs the boosted voltage VSUP2 as the voltage VOUT2 (=VSUP2×2), similarly to that in the first embodiment.

In such a voltage generating circuit, when the external power supply VCC is low (for example, 2.5V), both of the booster circuits CP1a and CP2 are operated, similarly to that in the first embodiment. When the external power supply VCC is high (for example, 3.7 V), only the booster circuit CP2 is operated.

### 1-4. Effects of First Embodiment

According to the first embodiment, it is possible to provide a semiconductor memory device including a voltage generating circuit in which the number of operated booster circuits can be changed in accordance with a change of the external power supply, and a peak current and consumed power can be reduced when a boosting operation is performed.

Effects of the first embodiment will be described below in detail.

For example, the semiconductor memory device of a NAND type flash memory and the like includes the voltage generating circuit which includes a plurality of booster circuits. In the voltage generating circuit, there is a case (comparative example) in which a supply of the voltage of the external power supply VCC (input voltage of the voltage generating circuit) to the booster circuit is controlled in order to control an output voltage of the booster circuit. In this case, it is difficult to reduce the peak current or the consumed power of the booster circuit in operation.

On the contrary, according to this embodiment, it is possible to control the number of operated booster circuits in accordance with a voltage value of the external power supply VCC. It is possible to reduce the peak current and the consumed power by stopping an operation of a booster circuit which is not needed to be driven.

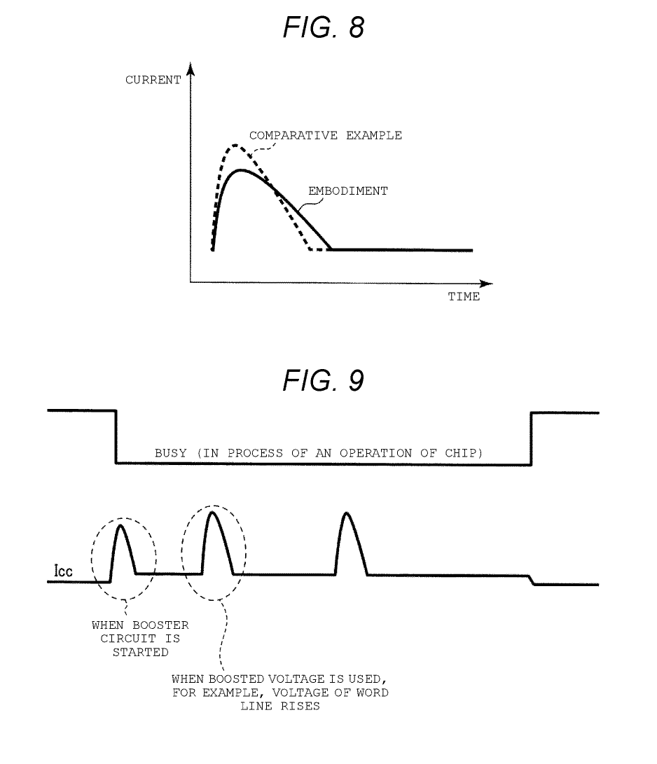

FIG. 8 illustrates a change between the peak currents of the voltage generating circuits in a case of employing this embodiment and a case (comparative example) of not employing this embodiment. As illustrated in FIG. 8, it is possible to suppress a peak of current values during the boosting operation in the voltage generating circuit in this embodiment, so as to be lower than that in the comparative example.

FIG. 9 illustrates a progress of a current Icc flowing in the voltage generating circuit of the semiconductor memory device. For example, as illustrated in FIG. 9, when operation of the voltage generating circuit is started, or when a voltage of a word line rises in a data write operation, a data erasing operation, or a data read operation, the current peaks as shown. Since these cases are timings at which the peak current is greater than that in other operations, the effect of reduction in the embodiment is larger at such timings.

The advantages are as follows. In this embodiment, since the operation of the booster circuit in which an operating state transitions to a non-operating state is changed in analog manner, fluctuation of the output voltage at a point of time when the number of operated booster circuits is changed is significantly small. The output voltage of the booster circuit has strongest dependency on the external power supply VCC. However, in this embodiment, it is possible to easily control the number of operated booster circuits in accordance with a change of the external power supply VCC.

In the modification example, it is possible to ensure boosting capability in a voltage range of the external power supply VCC wider than that in this embodiment, and to reduce the consumed power. Even when the external power supply is lower than that in this embodiment, since the booster circuit CP1a has high boosting capability, it is possible to boost the external power supply up to a desired voltage.

### 2. Second Embodiment

In a second embodiment, a plurality of transistors which have a threshold voltage different from each other are provided as the transistor which controls a supply of a voltage to the booster circuit. A difference from the first embodiment will be described below.

### 2-1. Voltage Generating Circuit

2-1-1. Circuit Configuration

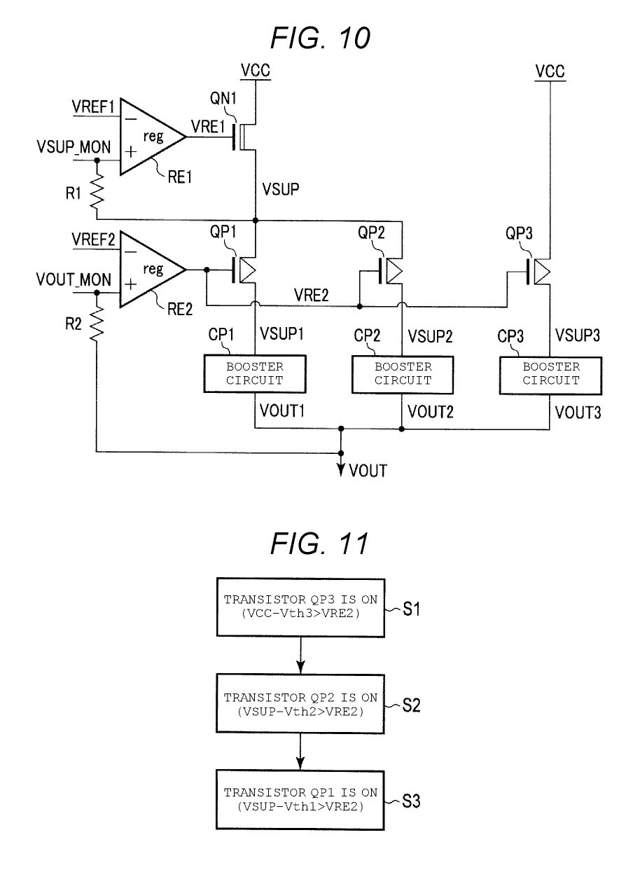

A configuration of a voltage generating circuit according to the second embodiment will be described with reference to FIG. 10.

As illustrated in FIG. 10, the sources of the nMOS transistor QN1 and the pMOS transistor QP1 are connected to the source of the pMOS transistor QP2. The drain of the pMOS transistor QP2 is connected to the booster circuit CP2. The output terminal of the regulator RE2 is connected to the gate of the pMOS transistor QP2.

The voltage generating circuit includes a pMOS transistor QP3 and a booster circuit CP3. The external power supply VCC is supplied to a source of the pMOS transistor QP3. A drain of the pMOS transistor QP3 is connected to the booster circuit CP3. The output terminal of the regulator RE2 is connected to a gate of the pMOS transistor QP3. Each of the booster circuits CP1, CP2, and CP3 includes the circuit illustrated in FIG. 3.

2-1-2. Operation

An operation of the voltage generating circuit according to the second embodiment will be described with reference to FIG. 11.

The external power supply VCC fluctuates in a range of 3.7 V to 2.5 V, for example. As an operation example, operations when the external power supply VCC is 3.7 V, 3.3 V, 2.8 V, and 2.5 V will be described below. It is assumed that threshold voltages of the pMOS transistors QP1 and QP3 are 0.7 V, and the threshold voltage of the pMOS transistor QP2 is 0.5 V.

(1) Case where External Power Supply VCC is Greater than 3.3 V and Equal to or Less than 3.7 V

When the external power supply VCC is greater than 3.3 V and equal to or less than 3.7V, the voltage generating circuit is operated as follows. Here, descriptions will be made for the case where the external power supply VCC is 3.7 V, as an example.

First, the external power supply VCC (3.7 V) is input to the source of the pMOS transistor QP3. The pMOS transistor QP3 transitions between the OFF state and the ON state, in accordance with a control voltage VRE2 supplied to the gate thereof. The pMOS transistor QP3 supplies the external power supply VCC to the booster circuit CP3 from the drain thereof in accordance with the transitioned state. The pMOS transistor QP3 is in the ON state when the control voltage VRE2 is equal to or less than “VCC−Vth” (3.0 V), and is in the OFF state when the control voltage VRE2 is greater than 3.0 V. An operation of outputting the control voltage VRE2 will be described below.

For example, since the control voltage VRE2 is 3.0 V, the pMOS transistor QP3 is in the ON state (S1). Thus, the pMOS transistor QP3 supplies the external power supply VCC which is input to the source of the pMOS transistor QP3, to the booster circuit CP3. The voltage supplied to the booster circuit CP3 is referred to as a voltage VSUP3. The booster circuit CP3 boosts the voltage VSUP3 and outputs the boosted voltage VSUP3 as a voltage VOUT3.

The external power supply VCC (3.7 V) is input to the drain of the depletion type nMOS transistor QN1. If the external power supply VCC (3.7 V) is input, the nMOS transistor QN1 steps down the external power supply VCC under a control of the regulator RE1, and thus the voltage at the source of the nMOS transistor QN1 is the voltage VSUP (2.7 V). The regulator RE1 receives a difference between the monitored voltage VSUP_MON and the reference voltage VREF1, and adjusts the control voltage VRE1 in accordance with the obtained difference, so as to keep the voltage VSUP to be constant (here, 2.7 V).

The voltage VSUP (2.7 V) is input to the source of the pMOS transistor QP1. The pMOS transistor QP1 is in the ON state when the control voltage VRE2 supplied to the gate of the pMOS transistor QP1 is equal to or less than “VSUP−Vth” (2.0 V) and is in the OFF state when the control voltage VRE2 is greater than 2.0 V. Since the control voltage VRE2 is 3.0 V, the pMOS transistor QP1 is in the OFF state. Thus, the pMOS transistor QP1 does not supply the voltage VSUP input to the source thereof, to the booster circuit CP1.

The voltage VSUP (2.7 V) is input to the source of the pMOS transistor QP2. The pMOS transistor QP2 is in the ON state when the control voltage VRE2 supplied to the gate of the pMOS transistor QP2 is equal to or less than “VSUP−Vth” (2.2 V) and is in the OFF state when the control voltage VRE2 is greater than 2.2 V. Since the control voltage VRE2 is 3.0 V, the pMOS transistor QP2 is in the OFF state. Thus, the pMOS transistor QP2 does not supply the voltage VSUP input to the source thereof, to the booster circuit CP2.

In this manner, when the external power supply VCC is 3.7 V, the pMOS transistors QP1 and QP2 are in the OFF state, and the pMOS transistor QP3 is in the ON state. Thus, the voltages VOUT1 and VOUT2 are not output and only the voltage VOUT3 is output. Accordingly, the voltage VOUT3 serves as the output voltage VOUT.

The output voltage VOUT is input to the non-inverting input terminal (+) of the regulator RE2 through the resistor R2. The reference voltage VREF2 is input to the inverting input terminal (−) of the regulator RE2. The regulator RE2 receives a difference between the monitored voltage VOUT_MON and the reference voltage VREF2, and adjusts the control voltage VRE2 in accordance with the obtained difference, so as to keep the output voltage VOUT to be a constant voltage. Thus, the output voltage VOUT is boosted up to a desired constant voltage.

(2) Case where External Power Supply VCC is Greater than 2.8 V and Equal to or Less than 3.3 V

When the external power supply VCC is greater than 2.8 V and equal to or less than 3.3V, the voltage generating circuit is operated as follows. Here, descriptions will be made by employing a case where the external power supply VCC is 3.3 V, as an example.

The external power supply VCC (3.3 V) is input to the source of the pMOS transistor QP3. The pMOS transistor QP3 is in the ON state when the control voltage VRE2 supplied to the gate thereof is equal to or less than “VCC−Vth” (2.6 V), and is in the OFF state when the control voltage VRE2 is greater than 2.6 V. For example, since the control voltage VRE2 is 2.1 V, the pMOS transistor QP3 is in the ON state, and supplies the external power supply VCC from the drain thereof to the booster circuit CP3. The booster circuit CP3 boosts the voltage VSUP3 and outputs the boosted voltage VSUP3 as the voltage VOUT3.

The external power supply VCC (3.3 V) is input to the drain of the depletion type nMOS transistor QN1. If the external power supply VCC (3.3V) is input, the nMOS transistor QN1 steps down the external power supply VCC under a control of the regulator RE1, and the voltage at the source of the nMOS transistor QN1 is the voltage VSUP (2.7 V).

The voltage VSUP (2.7 V) is input to the source of the pMOS transistor QP1. The pMOS transistor QP1 is in the ON state when the control voltage VRE2 is equal to or less than “VSUP−Vth” (2.0 V), and is in the OFF state when the control voltage VRE2 is greater than 2.0 V. Here, since the control voltage VRE2 is 2.1 V, the pMOS transistor QP1 is in the OFF state. Thus, the pMOS transistor QP1 does not supply the voltage VSUP input to the source thereof to the booster circuit CP1.

The voltage VSUP (2.7 V) is input to the source of the pMOS transistor QP2. The pMOS transistor QP2 is in the ON state when the control voltage VRE2 is equal to or less than “VSUP−Vth” (2.2 V), and is in the OFF state when the control voltage VRE2 is greater than 2.2 V. Here, since the control voltage VRE2 is 2.1 V, the pMOS transistor QP2 is in the ON state (S2). Thus, the pMOS transistor QP2 supplies the voltage VSUP input to the source thereof, to the booster circuit CP2. The booster circuit CP2 boosts the voltage VSUP2 and outputs the boosted voltage VSUP2 as the voltage VOUT2.

In this manner, when the external power supply VCC is 3.3 V, the pMOS transistor QP1 is in the OFF state, and the pMOS transistors QP2 and QP3 are in the ON state. Thus, the voltage VOUT1 is not output, and the voltage VOUT2 and the voltage VOUT3 are output. Accordingly, a voltage obtained by adding the voltage VOUT2 and the voltage VOUT3 serves as the output voltage VOUT. The output voltage VOUT is controlled by the regulator RE2 so as to be boosted up to a desired constant voltage.

(3) Case where External Power Supply VCC is from 2.7 V to 2.8 V

When the external power supply VCC is from 2.7 V to 2.8 V, the voltage generating circuit is operated as follows. Here, descriptions will be made by employing a case where the external power supply VCC is 2.8 V, as an example.

The external power supply VCC (2.8 V) is input to the source of the pMOS transistor QP3. The pMOS transistor QP3 is in the ON state when the control voltage VRE2 is equal to or less than “VCC−Vth” (2.1 V), and is in the OFF state when the control voltage VRE2 is greater than 2.1 V. For example, since the control voltage VRE2 is 1.9 V, the pMOS transistor QP3 is in the ON state, and supplies the external power supply VCC from the drain thereof to the booster circuit CP3. The booster circuit CP3 boosts the voltage VSUP3 and outputs the boosted voltage VSUP3 as the voltage VOUT3.

The external power supply VCC (2.8 V) is input to the drain of the depletion type nMOS transistor QN1. If the external power supply VCC (2.8V) is input, the nMOS transistor QN1 steps down the external power supply VCC under a control of the regulator RE1, and the voltage at the source of the nMOS transistor QN1 is the voltage VSUP (2.7 V).

The voltage VSUP (2.7 V) is input to the source of the pMOS transistor QP1. The pMOS transistor QP1 is in the ON state when the control voltage VRE2 is equal to or less than “VSUP−Vth” (2.0 V), and is in the OFF state when the control voltage VRE2 is greater than 2.0 V. Here, since the control voltage VRE2 is 1.9 V, the pMOS transistor QP1 is in the ON state (S3). Thus, the pMOS transistor QP1 supplies the voltage VSUP input to the source thereof, to the booster circuit CP1. The booster circuit CP1 boosts the voltage VSUP1 and outputs the boosted voltage VSUP1 as the voltage VOUT1.

The voltage VSUP (2.7 V) is input to the source of the pMOS transistor QP2. The pMOS transistor QP2 is in the ON state when the control voltage VRE2 is equal to or less than “VSUP−Vth” (2.2 V), and is in the OFF state when the control voltage VRE2 is greater than 2.2 V. Here, since the control voltage VRE2 is 1.9 V, the pMOS transistor QP2 is in the ON state. Thus, the pMOS transistor QP2 supplies the voltage VSUP input to the source thereof, to the booster circuit CP2. The booster circuit CP2 boosts the voltage VSUP2 and outputs the boosted voltage VSUP2 as the voltage VOUT2.

In this manner, when the external power supply VCC is 2.8 V, the pMOS transistors QP1, QP2, and QP3 are in the ON state. Thus, the voltages VOUT1, VOUT2, and VOUT3 are output. Accordingly, a voltage obtained by adding the voltages VOUT1, VOUT2, and VOUT3 is used as the output voltage VOUT. The output voltage VOUT is controlled by the regulator RE2 so as to be boosted up to a desired constant voltage.

(4) Case where External Power Supply VCC is Equal to or More than 2.5 V and Less than 2.7 V

When the external power supply VCC is equal to or more than 2.5 V and less than 2.7 V, the voltage generating circuit is operated as follows. Here, descriptions will be made by employing a case where the external power supply VCC is 2.5 V, as an example.

The external power supply VCC (2.5 V) is input to the source of the pMOS transistor QP3. The pMOS transistor QP3 is in the ON state when the control voltage VRE2 is equal to or less than “VCC−Vth” (1.8 V), and is in the OFF state when the control voltage VRE2 is greater than 1.8 V. For example, since the control voltage VRE2 is 1.8 V, the pMOS transistor QP3 is in the ON state, and supplies the external power supply VCC from the drain thereof to the booster circuit CP3. The booster circuit CP3 boosts the voltage VSUP3 and outputs the boosted voltage VSUP3 as the voltage VOUT3.

The external power supply VCC (2.5 V) is input to the drain of the depletion type nMOS transistor QN1. If the external power supply VCC (2.5 V) is input, the nMOS transistor QN1 is in the ON state, and thus a voltage of 2.5 V is transferred to the source of the nMOS transistor QN1.

The voltage VSUP (2.5 V) is input to the source of the pMOS transistor QP1. The pMOS transistor QP1 is in the ON state when the control voltage VRE2 is equal to or less than “VSUP−Vth” (1.8 V), and is in the OFF state when the control voltage VRE2 is greater than 1.8 V. Here, since the control voltage VRE2 is 1.8 V, the pMOS transistor QP1 is in the ON state. Thus, the pMOS transistor QP1 supplies the voltage VSUP input to the source thereof, to the booster circuit CP1. The booster circuit CP1 boosts the voltage VSUP1 and outputs the boosted voltage VSUP1 as the voltage VOUT1.

The voltage VSUP (2.5 V) is input to the source of the pMOS transistor QP2. The pMOS transistor QP2 is in the ON state when the control voltage VRE2 is equal to or less than “VSUP−Vth” (2.0 V), and is in the OFF state when the control voltage VRE2 is greater than 2.0 V. Here, since the control voltage VRE2 is 1.8 V, the pMOS transistor QP2 is in the ON state. Thus, the pMOS transistor QP2 supplies the voltage VSUP input to the source thereof, to the booster circuit CP2. The booster circuit CP2 boosts the voltage VSUP2 and outputs the boosted voltage VSUP2 as the voltage VOUT2.

In this manner, when the external power supply VCC is 2.5 V, the pMOS transistors QP1, QP2, and QP3 are in the ON state. Thus, the voltages VOUT1, VOUT2, and VOUT3 are output. Accordingly, a voltage obtained by adding the voltages VOUT1, VOUT2, and VOUT3 is used as the output voltage VOUT. The output voltage VOUT is controlled by the regulator RE2 so as to be boosted up to a desired constant voltage.

### 2-2. Modification Example

Similarly to the modification example according to the first embodiment, booster circuits may include the circuit illustrated in FIG. 3 connected in a plurality of stages for the booster circuits CP1, CP2, and CP3 in the second embodiment. In each of the booster circuits CP1, CP2, and CP3, the number of the stages may be different from each other.

### 2-3. Effects of Second Embodiment

According to the second embodiment, the threshold voltages of the transistors which control a supply of the voltage to the booster circuit are set to be different from each other, and thus it is possible to change the number of operated booster circuits in accordance with fluctuation of the external power supply, so as to have appropriate boosting capability. For example, in the above-described operation example, when the external power supply VCC is in a range of from 2.5 V to 2.8 V, the three booster circuits are operated. When the external power supply VCC is greater than 2.8 V and equal to or less than 3.3 V, the two booster circuits are operated. When the external power supply VCC is greater than 3.3 V and equal to or less than 3.7 V, the one booster circuit is operated.

Thus, it is possible to hold necessary boosting capability and not to perform an unnecessary operation of a booster circuit. It is possible to reduce a peak current and consumed power.

### 3. Other Modification Examples

The first, second, and third embodiments may be applied to various semiconductor devices which include, for example, a voltage generating circuit, a power supply circuit, a charge pump, and the like, regardless of a nonvolatile memory (for example, NAND type flash memory), a volatile memory, a system LSI, and the like.

In each of the embodiments and each of the modification examples,

(1) In a read operation, a voltage applied to a word line which is selected for a read operation of an A level is, for example, from 0 V to 0.55 V. However, it is not limited thereto. This voltage may be in any of the following ranges; a range of from 0.1 V to 0.24 V, a range of from 0.21 V to 0.31 V, a range of from 0.31 V to 0.4 V, a range of from 0.4 V to 0.5 V, and a range of from 0.5 V to 0.55 V.

A voltage applied to a word line which is selected for a read operation of a B level is, for example, from 1.5 V to 2.3 V. However, it is not limited thereto. This voltage may be in any of the following ranges; a range of from 1.65 V to 1.8 V, a range of from 1.8 V to 1.95 V, a range of from 1.95 V to 2.1 V, and a range of from 2.1 V to 2.3 V.

A voltage applied to a word line which is selected for a read operation of a C level is, for example, in a range of from 3.0 V to 4.0 V. However, it is not limited thereto. This voltage may be in any of the following ranges; a range of from 3.0 V to 3.2 V, a range of from 3.2V to 3.4 V, a range of from 3.4 V to 3.5 V, a range of from 3.5 V to 3.6 V, and a range of from 3.6 V to 4.0 V.

A period (tR) of time of the read operation may be, for example, in a range of from 25 μs to 38 μs, a range of from 38 μs to 70 μs, or a range of from 70 μs to 80 μs.

(2) A write operation includes a program operation and a verify operation. In the write operation, a voltage which is firstly applied to a word line selected during the program operation is, for example, in a range of from 13.7 V to 14.3 V. However, it is not limited thereto. This voltage may be, for example, in either of a range of from 13.7 V to 14.0 V and a range of from 14.0 V to 14.6 V. A voltage which is firstly applied to a word line selected when writing is performed with an odd-numbered word line may exchange a voltage which is firstly applied to a word line selected when writing is performed with an even-numbered word line.

When the program operation is performed by an incremental step pulse program (ISPP) method, a voltage of about 0.5 V is exemplified as a voltage for step-up.

A voltage applied to a non-selected word line may be in a range of from 6.0 V to 7.3 V, for example. However, it is not limited thereto. For example, this voltage may be in a range of from 7.3 V to 8.4 V, or be equal to or less than 6.0 V.

A path voltage to be applied may be changed in accordance with whether the non-selected word line is an odd-numbered word line or an even-numbered word line.

A period (tProg) of time for the write operation may be in a range of from 1,700 μs to 1,800 μs, a range of from 1,800 μs to 1,900 μs, or a range of from 1,900 μs to 2,000 μs, for example.

(3) In an erasing operation, a voltage which is firstly applied to a well (which is formed on a semiconductor substrate and the memory cells are arranged upwardly on the well) is, for example, in a range of from 12 V to 13.6 V. However, it is not limited thereto. For example, this voltage may be in any of the following ranges; a range of from 13.6 V to 14.8 V, a range of from 14.8 V to 19.0 V, a range of from 19.0 V to 19.8 V, and a range of from 19.8 V to 21 V.

A period (tErase) of time for the erasing operation may be in a range of from 3,000 μs to 4,000 μs, a range of from 4,000 μs to 5,000 μs, or a range of from 4,000 μs to 9,000 μs, for example.

(4) Regarding a structure of the memory cell, the memory cell has a charge storage layer arranged on a semiconductor substrate (silicon substrate) with a tunnel insulating film interposed between the charge storage layer and the semiconductor substrate. The charge storage layer has a film thickness of 4 nm to 10 nm. The charge storage layer may have a layered structure of an insulating film and a polysilicon film. The insulating film has a film thickness of 2 nm to 3 nm, and is formed of SiN, SiON, or the like. The polysilicon film has a film thickness of 3 nm to 8 nm. Metal such as Ru may be added to the polysilicon film. An insulating film is provided on the charge storage layer. For example, this insulating film is formed of a silicon oxide film interposed between a lower-layer High-k film which has a film thickness of 3 nm to 10 nm, and a higher-layer High-k film which has a film thickness of 3 nm to 10 nm. The silicon oxide film has a film thickness of 4 nm to 10 nm. As the High-k film, HfO and the like are exemplified. The film thickness of the silicon oxide film may be thicker than the film thickness of the High-k film. A control electrode is formed on the insulating film with a material for work function adjustment interposed between the control electrode and the insulating film. The control electrode has a film thickness of 30 nm to 70 nm. The material is formed to be a film having a film thickness of 3 nm to 10 nm. Here, the material for work function adjustment is a metal oxide film of TaO or the like, or a metal nitride film of TaN or the like. W or the like may be used for the control electrode.

An air gap may be formed between memory cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A voltage generating circuit comprising:
a first booster circuit that generates a first boosted voltage from a voltage supplied to an input thereof;
a first transistor having a first terminal electrically connected to the input of the first booster circuit;
a second booster circuit that generates a second boosted voltage from a voltage supplied to an input thereof; and
a second transistor having a first terminal electrically connected to the input of the second booster circuit and a second terminal electrically connected to a voltage source; and
a control circuit electrically connected between the voltage source and a second terminal of the first transistor, the control circuit configured to cut off the voltage source from the second terminal of the first transistor in accordance with a voltage level of the voltage source.

2. The circuit according to claim 1, wherein the control circuit includes:
a third transistor having a first terminal electrically connected to the second terminal of the first transistor, a second terminal electrically connected to the voltage source, and a gate; and
a regulator having a first input to which a reference voltage is applied, a second input electrically connected to the first terminal of the third transistor, and an output electrically connected to the gate of the third transistor, the regulator configured to generate a control signal at the output thereof in accordance with the voltage levels of the first and second inputs.

3. The circuit according to claim 2, wherein the third transistor cuts off the voltage source from the second terminal of the first transistor if the voltage level of the voltage source exceeds a threshold level.

4. The circuit according to claim 1, further comprising:
a regulator having a first input to which a reference voltage is applied, a second input electrically connected to an output terminal of the first booster circuit through which the first boosted voltage is output and an output terminal of the second booster circuit through which the second boosted voltage is output, and an output electrically connected to gates of the first and second transistors, the regulator configured to generate a control signal at the output thereof in accordance with the voltage levels of the first and second inputs.

5. The circuit according to claim 4, wherein the first transistor cuts off a voltage supplied to the input of the first booster circuit and the second transistor cuts off a voltage supplied to the input of the second booster circuit, if a sum of voltage levels at the output terminals of the first and second booster circuits exceeds a threshold level.

6. The circuit according to claim 1, further comprising:
a third booster circuit that generates a third boosted voltage from a voltage supplied to an input thereof; and
a third transistor having a first terminal electrically connected to the input of the third booster circuit,
wherein the control circuit is electrically connected between the voltage source and a second terminal of the third transistor, the control circuit configured to cut off the voltage source from the second terminal of the third transistor in accordance with the voltage level of the voltage source.

7. The circuit according to claim 6, wherein the third transistor has a threshold voltage different from a threshold voltage of the first transistor.

8. The circuit according to claim 1, wherein
the first booster circuit has a boosting performance different from a boosting performance of the second booster circuit.

9. A semiconductor memory device comprising:
a memory cell;
a word line that is connected to the memory cell;
a first booster circuit that generates a first boosted voltage from a voltage supplied to an input thereof;
a first transistor having a first terminal electrically connected to the input of the first booster circuit;
a second booster circuit that generates a second boosted voltage from a voltage supplied to an input thereof; and
a second transistor having a first terminal electrically connected to the input of the second booster circuit and a second terminal electrically connected to a voltage source; and
a control circuit electrically connected between the voltage source and a second terminal of the first transistor, the control circuit configured to cut off the voltage source from the second terminal of the first transistor in accordance with a voltage level of the voltage source,
wherein a voltage to be supplied to the word line is generated from the first and second boosted voltages.

10. The device according to claim 9, wherein the control circuit includes:
a third transistor having a first terminal electrically connected to the second terminal of the first transistor, a second terminal electrically connected to the voltage source, and a gate; and
a regulator having a first input to which a reference voltage is applied, a second input electrically connected to the first terminal of the third transistor, and an output electrically connected to the gate of the third transistor, the regulator configured to generate a control signal at the output thereof in accordance with the voltage levels of the first and second inputs.

11. The device according to claim 10, wherein the third transistor cuts off the voltage source from the second terminal of the first transistor if the voltage level of the voltage source exceeds a threshold level.

12. The device according to claim 9, further comprising:
a regulator having a first input to which a reference voltage is applied, a second input electrically connected to an output terminal of the first booster circuit through which the first boosted voltage is output and an output terminal of the second booster circuit through which the second boosted voltage is output, and an output electrically connected to gates of the first and second transistors, the regulator configured to generate a control signal at the output thereof in accordance with the voltage levels of the first and second inputs.

13. The device according to claim 12, wherein the first transistor cuts off a voltage supplied to the input of the first booster circuit and the second transistor cuts off a voltage supplied to the input of the second booster circuit, if a sum of voltage levels at the output terminals of the first and second booster circuits exceeds a threshold level.

14. The device according to claim 9, further comprising:
a third booster circuit that generates a third boosted voltage from a voltage supplied to an input thereof; and
a third transistor having a first terminal electrically connected to the input of the third booster circuit,
wherein the control circuit is electrically connected between the voltage source and a second terminal of the third transistor, the control circuit configured to cut off the voltage source from the second terminal of the third transistor in accordance with the voltage level of the voltage source.

15. The device according to claim 14, wherein the third transistor has a threshold voltage different from a threshold voltage of the first transistor.

16. The device according to claim 9, wherein
the first booster circuit has a boosting performance different from a boosting performance of the second booster circuit.

17. A method of boosting an input voltage supplied to a voltage generating circuit including a first booster circuit that generates a first boosted voltage from a voltage supplied to an input thereof and a second booster circuit that generates a second boosted voltage from a voltage supplied to an input thereof, said method comprising:
regulating a voltage level of the voltage supplied to inputs of the first and second booster circuits based on a voltage level of the first and second boosted voltages; and
cutting off an electrical connection between a voltage source and the first booster circuit based on a voltage level of the voltage source.

18. The method according to claim 17, wherein the voltage generating circuit further includes a third booster circuit that generates a third boosted voltage from a voltage supplied to an input thereof, and an electrical connection between the voltage source and the third booster circuit is cut off based on the voltage level of the voltage source.

19. The method according to claim 18, wherein the third transistor has a threshold voltage different from a threshold voltage of the first transistor.

20. The method according to claim 17, wherein
the first booster circuit has a boosting performance different from a boosting performance of the second booster circuit.
